(19) United States
(12) Patent Application Publication
(10) Pub. No.: US 2017/0198389 A1
(43) Pub. Date: Jul. 13, 2017

(54) EVAPORATION DEVICE AND EVAPORATION SYSTEM

(71) Applicants: Boe Technology Group Co., Ltd., Beijing (CN); ORDOS YUANSHENG OPTOELECTRONICS CO., LTD., Inner Mongolia (CN)

(72) Inventors: Jianqiang Wang, Beijing (CN); Qun Ma, Beijing (CN); Haizhi Xiu, Beijing (CN); Yuwu Lv, Beijing (CN); Chonkyu Min, Beijing (CN)

(21) Appl. No.: 15/321,014

(22) PCT Filed: Mar. 11, 2016
(86) PCT No.: PCT/CN2016/076133

§ 371 Date: Dec. 21, 2016

(30) Foreign Application Priority Data
May 25, 2015 (CN) 201510272142.8

(51) Int. Cl. C23C 14/26; C23C 14/54

(52) U.S. Cl. CPC C23C 14/26; C23C 14/54

(57) ABSTRACT

An evaporation device and an evaporation system are provided. The evaporation device comprises a first heating part; a heat transfer part comprising a first and second heat transfer member, wherein the second heat transfer member surrounds the first heat transfer member and is spaced apart from the first heat transfer member by a predefined distance, a space between the first and second heat transfer member is configured to accommodate an evaporation material, and the heat transfer part is configured to transfer heat from the first heating part to the evaporation material for sublimating the evaporation material; and an ejection part for ejecting the evaporation material which has been heated and sublimated by the heat transfer part. The evaporation system comprises the evaporation device.

### RELATED APPLICATIONS

The present application is the U.S. national phase entry of PCT/CN2016/076133, with an international filing date of Mar. 11, 2016, which claims the benefit of Chinese Patent Application No. 201510272142.8, filed on May 25, 2015, the entire disclosures of which are incorporated herein by reference.

### TECHNICAL FIELD

The present invention relates to the field of evaporating an organic material, and in particular to an evaporation device and an evaporation system.

### BACKGROUND

Currently, the field of organic display device is developing rapidly, and evaporation of an organic film has become a critical factor in this field. During evaporation of an organic film, the quality of an evaporation device has a direct effect on the quality of the evaporated organic film. Besides, different materials pose different requirements for the evaporation device. Generally a high purity organic material is solid powder, so that some existing evaporation devices (e.g., an evaporation susceptor) are not suitable for the high purity organic material.

As shown in FIG. 1, in an existing evaporation device, a heat transfer part 120′ is generally a round barrel. The organic material is more prone to be heated at the barrel wall and the barrel bottom in the round barrel heat transfer part, while is less prone to be heated at position close to the middle portion. Thus, the organic material is not uniformly heated. The organic material close to the inner wall of the heat transfer part has a high temperature and is sublimate firstly. The organic material which has not been evaporated forms a cone in the heat transfer part, and the heat transfer part is exposed in its inner wall, which leads to loss in heat energy. In addition, the organic material which is sublimated from the barrel bottom may condensate when it comes across the organic material at the top at a low temperature, and thus may hinder ejection of vapor. The heat transfer part is at a different temperature from the ejection part. When the sublimated organic material come across the ejection part at a low temperature, the sublimated organic material is cooled to condensate and thus blocks the ejection part. A system which can automatically regulate the temperature and ejecting rate of the evaporation device to automatically control evaporation of an organic film, is currently not available.

Therefore, it is desired to provide an evaporation device in which the organic material is heated uniformly, and the ejection part is prevent from being blocked. It is also desired to provide a system which can automatically control the temperature and ejecting rate of the evaporation device.

### SUMMARY

According to an embodiment of the present invention, it is provided an evaporation device, comprising:

a first heating part;

a heat transfer part, wherein the heat transfer part comprises a first heat transfer member and a second heat transfer member, the second heat transfer member surrounds the first heat transfer member and is spaced apart from the first heat transfer member by a predefined distance, a space between the first heat transfer member and the second heat transfer member is configured to accommodate an evaporation material, and the heat transfer part is configured to transfer heat from the first heating part to the evaporation material for sublimating the evaporation material; and

an ejection part, which is configured to eject the evaporation material which has been heated and sublimated by the heat transfer part.

For example, in an embodiment of the present invention, the first heat transfer part has a columnar shape, and has a cross section of a circle, ellipse, square, pentagon, or hexagon.

For example, in an embodiment of the present invention, the second heat transfer member has a ring structure which is centered at the first heat transfer member.

For example, in an embodiment of the present invention, the evaporation device comprises a the plurality of second heat transfer members, and two neighboring second heat transfer members are spaced by a predefined distance to form a space for accommodating the evaporation material.

For example, in an embodiment of the present invention, the predefined distance is about 1.0-2.0 cm.

For example, in an embodiment of the present invention,

the second heat transfer member closest to the first heat transfer member is the highest;

the second heat transfer member farthest from the first heat transfer member is the lowest; and

with an increase in the distance between the second heat transfer members and the first heat transfer member, the second heat transfer members successively decrease in height, so that the plurality of second heat transfer members have a cone shape as a whole.

For example, in an embodiment of the present invention, difference in height between two neighboring second heat transfer members is about 1.0-1.5 cm.

For example, in an embodiment of the present invention, the ejection part comprises a nozzle.

For example, in an embodiment of the present invention, the nozzle is provided with a second heating part.

For example, in an embodiment of the present invention, the second heating part is a hot wire which is wound around the nozzle.

According to an embodiment of the present invention, it is provided an evaporation system, comprising the evaporation device as described above.

For example, in an embodiment of the present invention, the evaporation system further comprises a monitoring device, a PLC control device, and a temperature controller,

wherein the monitoring device is configured to monitor an ejecting rate of the evaporation material, and

the PLC control device communicates with the monitoring device to receive the ejecting rate obtained by the monitoring device, determines a magnitude of the ejecting rate, and on basis of the determined magnitude, gives an instruction to the temperature controller to regulate heating temperature of the first heating part to provide a stable ejecting rate.

For example, in an embodiment of the present invention, when the ejecting rate is larger than a first threshold, the PLC control device gives an instruction to the temperature controller, and the instruction instructs the temperature controller to decrease heating temperature of the first heating part, so as to decrease the ejecting rate; and

when the ejecting rate is smaller than the first threshold, the PLC control device gives an instruction to the temperature controller, and the instruction instructs the temperature controller to increase heating temperature of the first heating part, so as to increase the ejecting rate.

For example, in an embodiment of the present invention, the evaporation system further comprises a pulse current regulating device,

wherein the pulse current regulating device communicates with the PLC control device, and on basis of the determined magnitude of the ejecting rate, the PLC control device gives an instruction to the pulse current regulating device to regulate heating temperature of the second heating part of the ejection part, so as to provide a stable ejecting rate.

For example, in an embodiment of the present invention, when the ejecting rate is larger than a second threshold, the PLC control device gives an instruction to the pulse current regulating device, and the instruction instructs the pulse current regulating device to decrease heating temperature of the second heating part, so as to decrease the ejecting rate; and

when the ejecting rate is smaller than the second threshold, the PLC control device gives an instruction to the pulse current regulating device, and the instruction instructs the pulse current regulating device to increase heating temperature of the second heating part, so as to increase the ejecting rate and prevent the ejection part from being blocked.

### BRIEF DESCRIPTION OF THE DRAWINGS

FIG. 1 is a cross-sectional view illustrating an existing heat transfer part;

FIG. 2 is a cross-sectional view illustrating an evaporation device in an embodiment of the present invention;

FIG. 3 is a perspective view illustrating heat transfer part in an embodiment of the present invention; and

FIG. 4 is a schematic view illustrating an evaporation system in an embodiment of the present invention.

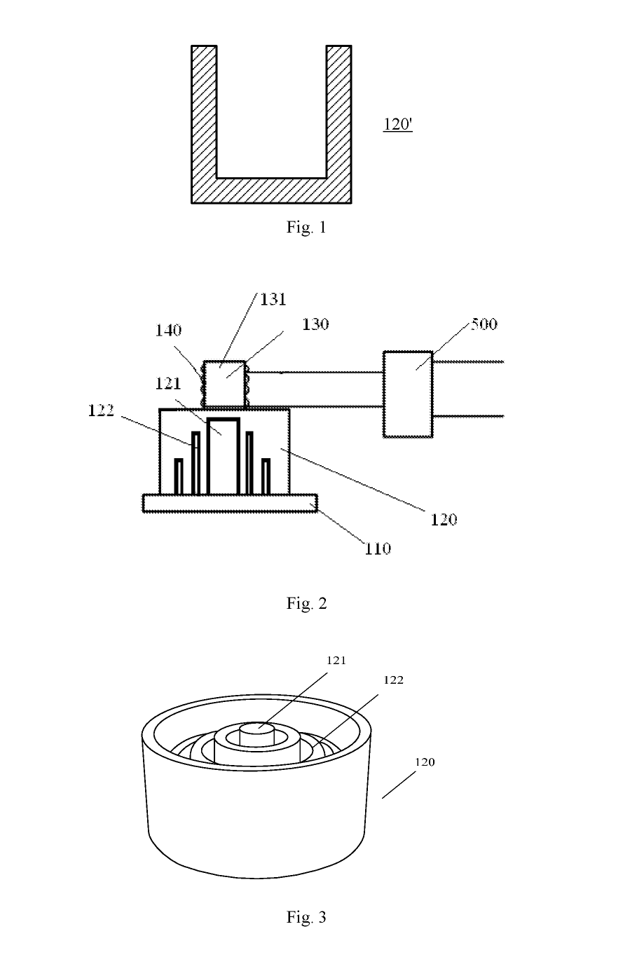

### DETAILED DESCRIPTION OF EMBODIMENTS

The specific embodiments of the present invention shall be further described in the follow text with reference to the figures and the embodiments. The following embodiments are only used for explaining more clearly the technical solution of the present invention rather than limiting the protection scope of the present invention.

Reference numerals: evaporation device 100, first heating part 110, heat transfer part 120, 120′, first heat transfer member 121, second heat transfer member 122, ejection part 130, nozzle 131, second heating part 140, monitoring device 200, PLC (programmable logic controller) control device 300, the temperature controller 400, pulse current regulating device 500.

As shown in FIG. 2, in an exemplary embodiment of the present invention, an evaporation device 100 comprises a first heating part 110 and a heat transfer part 120. For example, the first heating part 110 can be arranged below the heat transfer part 120. The heat transfer part 120 comprises a first heat transfer member 121 which has a columnar shape, and a second heat transfer member 122 which surrounds the first heat transfer member 121 and is spaced apart from the first heat transfer member 121 by a predefined distance. A space between the first heat transfer member 121 and the second heat transfer member 122 is configured to accommodate an evaporation material (i.e., material to be evaporated). The heat transfer part 120 is configured to transfer heat from the first heating part 110 to the evaporation material so that the evaporation material is sublimated. The evaporation device 100 further comprises an ejection part 130, which is configured to eject the evaporation material which has been heated and sublimated by the heat transfer part 120.

In an exemplary embodiment of the present invention, the heat transfer part is provided with the columnar first heat transfer member 121 and the second heat transfer member 122 surrounding the first heat transfer member 121. As a result, the evaporation material (e.g., an organic material) which is placed in the heat transfer part 120 (the space between the first heat transfer member 121 and the second heat transfer member 122) is heated in an increased area, the evaporation material is heated more uniformly, and an enhanced evaporation effect is realized. In particular, by means of the columnar first heat transfer member 121, the problem that the organic material in the middle portion of the heat transfer part is less heated and a cone-shaped organic material remains is overcome.

In addition, in an exemplary embodiment of the present invention, the heat transfer part 120 can have a round barrel shape for transferring heat. The second heat transfer member 122 for containing the evaporation material can also have a shape of square, hexagon or the like, to surround the columnar first heat transfer member. The second heat transfer member 122 and the first heat transfer member 121 form a space for containing the organic material, and the second heat transfer member 122 further functions to transfer heat. The second heat transfer member 122 can have a cross section of various shapes, such as a circle, an ellipse, a quadrilateral, a pentagon, a hexagon, which is selected as needed. The heat transfer part 120 is generally made from aluminum titanium alloy or stainless steel, so as to realize enhanced effect of heat transferring.

In an embodiment of the present invention, as shown in FIG. 3, the second heat transfer member 122 has a ring structure, and the ring structure is centered at the first heat transfer member 121.

In an exemplary embodiment of the present invention, the second heat transfer member 122 has a ring structure, and the ring structure is centered at the first heat transfer member 121. Namely, the first heat transfer member 121 has a columnar shape, and has a cross section of a circle, an ellipse, a square, a pentagon, a hexagon, or the like. The second heat transfer member 122 surrounds the first heat transfer member 121, and has a cross-sectional shape. The cross-sectional shape is a circle, and a center of the circle is located at a central point of the cross-sectional shape. The circle surrounds, but does not intersect, a cross section of the first heat transfer member 121.

In an exemplary embodiment of the present invention, as shown in FIG. 3, there are a plurality of the second heat transfer members 122. Two neighboring second heat transfer members 122 are spaced by a predefined distance to form a space for accommodating the evaporation material.

In an exemplary embodiment of the present invention, there are a plurality of second heat transfer members 122. For example, there is one, two, or a plurality of second heat transfer members 122. The evaporation material is placed between the second heat transfer members 122 or between the second heat transfer members 122 and the first heat transfer member 121. This increases a contact area between the evaporation material and the heat transfer part 120, so that the evaporation material is heated uniformly, and the evaporated film is more uniform.

In an embodiment of the present invention, the predefined distance is about 1.0-2.0 cm.

In an exemplary embodiment of the present invention, a distance between two neighboring second heat transfer members is relatively small, and the contact area between the evaporation material and the heat transfer part is increased.

In an embodiment of the present invention, as shown in FIG. 3, the second heat transfer member 122 closest to the first heat transfer member is the highest, and the second heat transfer member 122 farthest from the first heat transfer member 121 is the lowest. With an increase in the distance between the second heat transfer members 122 and the first heat transfer member 121, the second heat transfer members 122 successively decrease in height, so that the plurality of second heat transfer members 122 have a cone shape as a whole.

In an exemplary embodiment of the present invention, the plurality of second heat transfer members 122 are arranged, and multiple spaces can be provided for accommodating the evaporation material, so that the evaporation material is heated more uniformly. In an exemplary embodiment of the present invention, the second heat transfer members 122 successively decrease in height in a direction away from the first heat transfer member 121, so that the heat transfer part 120 exhibits a conical structure. In this manner, it is possible to overcome the problem in the prior art that the organic evaporation material is not heated uniformly since the heat transfer part only has a peripheral barrel structure, and organic evaporation material stacks into a cone which is difficult to sublimate. By means of the evaporation device of the present exemplary embodiment, the plurality of second heat transfer members 122 successively decrease in height, so that the heat transfer part 120 has a conical structure as a whole, and the organic material in the cone can be heated uniformly. Thus, all of the organic material can be sublimated and ejected to form a uniform evaporated film.

In an embodiment of the present invention, difference in height between two neighboring second heat transfer members 122 is about 1.0-1.5 cm, e.g., 1.2 cm.

In an embodiment of the present invention, a plurality of second heat transfer members 122 are provided, the difference in height is relatively small, and the second heat transfer members 122 can be heated uniformly, thus completely overcome the problem that a cone-shaped evaporation material remains. According to an embodiment of the present invention, difference in height two neighboring second heat transfer members 122 is about 1.0-1.5 cm. The second heat transfer member 122 generally has a thickness of 0.3-0.5 mm, e.g., 0.4 mm. The second heat transfer member 122 has a small thickness, so that heat is transferred uniformly and the organic material is heated uniformly.

In an exemplary embodiment of the present invention, as shown in FIG. 2, the ejection part 130 comprises a nozzle 131. The nozzle 131 is provided with a second heating part 140.

In an exemplary embodiment of the present invention, the second heating part 140 is arranged on the nozzle 131. As a result, the nozzle 131 is maintained a relatively constant temperature, thus preventing the evaporation material from solidifying to block the nozzle 131. Thus, the problem in the prior art that the nozzle tends to be blocked is overcome.

In an exemplary embodiment of the present invention, as shown in FIG. 2, the ejection part 130 comprises the nozzle 131, and the nozzle 131 is provided with the second heating part 140.

In an exemplary embodiment of the present invention, the second heating part 140 is a hot wire, so that it is convenient to control the heating duration and period, and the problem that the nozzle is blocked is prevented.

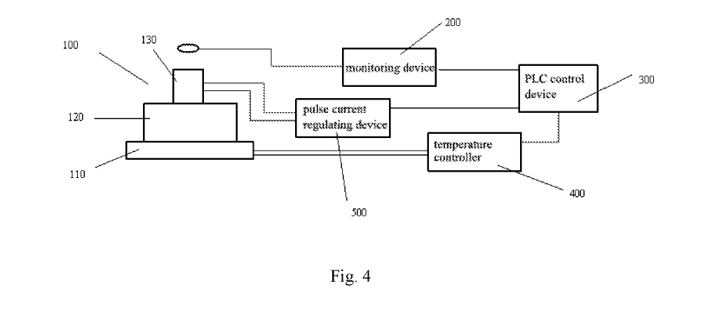

In an exemplary embodiment of the present invention, it is provided an evaporation system. As shown in FIG. 4, the evaporation system comprises the evaporation device 100 as described above, a monitoring device 200, a PLC control device 300, and a temperature controller 400. The monitoring device 200 is configured to monitor an ejecting rate of the evaporation material. The PLC control device 300 communicates with the monitoring device 200 to receive the ejecting rate obtained by the monitoring device 200. The PLC control device 300 determines a magnitude of the ejecting rate, and on basis of the determined magnitude, gives an instruction to the temperature controller 400 to regulate heating temperature of the first heating part 110, so as to provide a stable ejecting rate. When the ejecting rate is larger than a first threshold, the PLC control device 300 gives an instruction to the temperature controller 400, and the instruction instructs the temperature controller 400 to decrease heating temperature of the first heating part 110, so as to decrease the ejecting rate. When the ejecting rate is smaller than the first threshold, the PLC control device 300 gives an instruction to the temperature controller 400, and the instruction instructs the temperature controller to increase heating temperature of the first heating part 110, so as to increase the ejecting rate.

The evaporation system not only can heat the evaporation material uniformly, but also can be automatically controlled. The monitoring device 200 monitors the ejection part 130 to collect data about the ejecting rate, and transmits the collected data to the PLC control device 300. The PLC control device 300 processes the data. If it is decided that the ejecting rate is too large, the PLC control device 300 gives an instruction to the temperature controller 400 to decrease temperature, so that the temperature controller 400 decreases heating temperature which further decrease the ejecting rate. If it is decided that the ejecting rate is too small, the PLC control device 300 gives an instruction to the temperature controller 400 to increase temperature, so that the temperature controller 400 increases heating temperature which further increases the ejecting rate. By setting the temperature and ejecting rate via the PLC control device 300, the ejecting rate is maintained constant, so that uniformity of the evaporated film is improved.

In an exemplary embodiment of the present invention, as shown in FIG. 4, the evaporation system further comprises a pulse current regulating device 500. The pulse current regulating device 500 communicates with the PLC control device 300. On basis of the determined magnitude of the ejecting rate, the PLC control device 300 gives an instruction to the pulse current regulating device 500 to regulate heating temperature of the second heating part 140, so as to provide a stable ejecting rate. When the ejecting rate is larger than a second threshold, the PLC control device 300 gives an instruction to the pulse current regulating device 500, and the instruction instructs the pulse current regulating device 500 to decrease heating temperature of the second heating part 140, so as to decrease the ejecting rate. When the ejecting rate is smaller than the second threshold, the PLC control device 300 gives an instruction to the pulse current regulating device 500, and the instruction instructs the pulse current regulating device 500 to increase heating temperature of the second heating part 140, so as to increase the ejecting rate and prevent the ejection part 130 from being blocked.

In an exemplary embodiment of the present invention, the evaporation system can further be automatically controlled, so as to prevent the nozzle from being blocked. In an exemplary embodiment of the present invention, the pulse current regulating device 500 can be a periodic pulse current regulating device. When the data detected by the monitoring device 200 is transmitted to the PLC control device 300, and the PLC control device 300 processes the data and determines that the ejecting rate is relatively large, the PLC control device 300 gives an instruction to the pulse current regulating device 500 to decrease the current through the second heating part 140 (e.g., a hot wire). As a result, temperature of the nozzle 131 in the ejection part 130 is decreased, and the ejecting rate is decreased. When the PLC control device 300 processes the data and determines that the ejecting rate is relatively small, the PLC control device 300 gives an instruction to the pulse current regulating device 500 to increase the current through the second heating part 140. As a result, temperature of the nozzle 131 in the ejection part 130 is increased, and the ejecting rate is increased. Thus, the nozzle 131 is prevented from being blocked, and the ejecting rate is maintained substantially constant. Even in case the nozzle is blocked, and the ejecting rate decrease or even decreases to 0 (i.e., no organic material is ejected), it is possible to sublimate the organic material which is blocked in the nozzle 131 by regulating heating, thus overcoming the problem that the nozzle is blocked.

By means of the evaporation device of embodiments of the present invention, the organic material to be evaporated can be heated uniformly. The ejection part is further provided with the second heating part to prevent the ejection part from being blocked, so as to improve the quality of the evaporated film. In addition, by means of the evaporation system of embodiments of the present invention, the heating rate and ejecting rate can be automatically regulated, so as to improve the quality of the evaporated film.

Apparently, the person with ordinary skill in the art can make various modifications and variations to the present invention without departing from the spirit and the scope of the present invention. In this way, provided that these modifications and variations of the present invention belong to the scopes of the claims of the present invention and the equivalent technologies thereof, the present invention also intends to encompass these modifications and variations.

1. An evaporation device, comprising:
a first heating part;
a heat transfer part, wherein the heat transfer part comprises a first heat transfer member and a second heat transfer member, the second heat transfer member surrounds the first heat transfer member and is spaced apart from the first heat transfer member by a predefined distance, a space between the first heat transfer member and the second heat transfer member is configured to accommodate an evaporation material, and the heat transfer part is configured to transfer heat from the first heating part to the evaporation material for sublimating the evaporation material; and
an ejection part, which is configured to eject the evaporation material which has been heated and sublimated by the heat transfer part.

2. The evaporation device of claim 1, wherein the first heat transfer part has a columnar shape, and has a cross section of a circle, ellipse, square, pentagon, or hexagon.

3. The evaporation device of claim 1, wherein the second heat transfer member has a ring structure which is centered at the first heat transfer member.

4. The evaporation device of claim 3, wherein the evaporation device comprises a the plurality of second heat transfer members, and two neighboring second heat transfer members are spaced by a predefined distance to form a space for accommodating the evaporation material.

5. The evaporation device of claim 4, wherein the predefined distance is about 1.0-2.0 cm.

6. The evaporation device of claim 4, wherein
the second heat transfer member closest to the first heat transfer member is the highest;
the second heat transfer member farthest from the first heat transfer member is the lowest; and
with an increase in the distance between the second heat transfer members and the first heat transfer member, the second heat transfer members successively decrease in height, so that the plurality of second heat transfer members have a cone shape as a whole.

7. The evaporation device of claim 6, wherein difference in height between two neighboring second heat transfer members is about 1.0-1.5 cm.

8. The evaporation device of claim 1, wherein the ejection part comprises a nozzle.

9. The evaporation device of claim 8, wherein the nozzle is provided with a second heating part.

10. The evaporation device of claim 9, wherein the second heating part is a hot wire which is wound around the nozzle.

11. An evaporation system, comprising the an evaporation device, wherein the evaporation device comprises:
a first heating part;
a heat transfer part, wherein the heat transfer part comprises a first heat transfer member and a second heat transfer member, the second heat transfer member surrounds the first heat transfer member and is spaced apart from the first heat transfer member by a predefined distance, a space between the first heat transfer member and the second heat transfer member is configured to accommodate an evaporation material, and the heat transfer part is configured to transfer heat from the first heating part to the evaporation material for sublimating the evaporation material; and
an ejection part, which is configured to eject the evaporation material which has been heated and sublimated by the heat transfer part.

12. The evaporation system of claim 11, further comprising a monitoring device, a PLC control device, and a temperature controller,
wherein the monitoring device is configured to monitor an ejecting rate of the evaporation material, and
the PLC control device communicates with the monitoring device to receive the ejecting rate obtained by the monitoring device, determines a magnitude of the ejecting rate, and on basis of the determined magnitude, gives an instruction to the temperature controller to regulate heating temperature of the first heating part to provide a stable ejecting rate.

13. The evaporation system of claim 12,
wherein_when the ejecting rate is larger than a first threshold, the PLC control device gives an instruction to the temperature controller, and the instruction instructs the temperature controller to decrease heating temperature of the first heating part, so as to decrease the ejecting rate.

14. The evaporation system of claim 12, further comprising a pulse current regulating device,
wherein the pulse current regulating device communicates with the PLC control device, and on basis of the determined magnitude of the ejecting rate, the PLC control device gives an instruction to the pulse current regulating device to regulate heating temperature of the second heating part of the ejection part, so as to provide a stable ejecting rate.

15. The evaporation system of claim 14,
wherein_when the ejecting rate is larger than a second threshold, the PLC control device gives an instruction to the pulse current regulating device, and the instruction instructs the pulse current regulating device to decrease heating temperature of the second heating part, so as to decrease the ejecting rate.

16. The evaporation system of claim 12, wherein when the ejecting rate is smaller than the first threshold, the PLC control device gives an instruction to the temperature controller, and the instruction instructs the temperature controller to increase heating temperature of the first heating part, so as to increase the ejecting rate.

17. The evaporation system of claim 14, wherein when the ejecting rate is smaller than the second threshold, the PLC control device gives an instruction to the pulse current regulating device, and the instruction instructs the pulse current regulating device to increase heating temperature of the second heating part, so as to increase the ejecting rate and prevent the ejection part from being blocked.
